(19) United States
(12) Patent Application Publication
(10) Pub. No.: US 2002/0149118 A1
(43) Pub. Date: Oct. 17, 2002

(54) Semiconductor device and bump formation method

(76) Inventors: Katsumi Yamaguchi, Beppu-shi (JP); Takako Yamaguchi, Beppu-shi (JP); Tomohiro Okazaki, Beppu-shi (JP)

Correspondence Address: TEXAS INSTRUMENTS INCORPORATED, P O BOX 655474, M/S 3999, DALLAS, TX, 75265

(21) Appl. No.: 10/087,556

(22) Filed: Mar. 1, 2002

(30) Foreign Application Priority Data
Mar. 6, 2001 (JP) 2001-061381

(51) Int. Cl. H01L 23/48; H01L 23/52; H01L 29/40

(52) U.S. Cl. 257/778

(57) ABSTRACT

An object of the invention is to improve the position, shape, and size of a bump in order to realize highly reliable flip-chip mounting. In the case of the semiconductor device of this embodiment, a stacked bump 14 is provided on electrode pad 12 created on the main surface of semiconductor chip 10. That is, said bump 14 comprises columnar pedestal part 14a and columnar tail part 14b having a smaller diameter than that of pedestal part 14a. Peak plane of tail part 14b (peak plane of the bump) and the top surface of pedestal part 14a are both flat. Said bump 14 is created through gold plating, for example, using a resist (photolithography) technology and a plating technology.

### FIELD OF INVENTION

The present invention pertains to a semiconductor device implementation technology. More specifically, it pertains to a bump structure and a bump formation method in the case of the flip-chip scheme.

### BACKGROUND OF THE INVENTION

Flip-chip scheme is of a wireless bonding method, an implementation technology in which a bump is created on the electrode on a semiconductor chip, and the chip is placed face down (facing downward) to achieve direct connection with the conductive pattern surface on the printed board.

Stud type bump 100 shown in FIG. 8 has been known as a bump created using gold as the material. In general, this kind of stud bump 100 is created using a gold wire. More specifically, the tip of a gold wire (not illustrated) sticking out of a capillary (not illustrated) is melted using a spark or a flame from a torch (not illustrated), formed into a ball, placed against electrode pad 104 on semiconductor chip 102, and applied with a pressure and an ultrasonic wave via the capillary in order to bond the tip of the gold wire to electrode pad 104. Next, the gold wire gets torn near its root as it is raised, and a stud-like gold wire tip part, that is, bump 100, remains on electrode pad 104. Furthermore, heat at a prescribed temperature is applied from the side of a stage (not illustrated) on which semiconductor chip 102 is mounted during the working. As such, said stud bump 100 is configured with near-hemispheric pedestal part 100a created through bonding (ball bond) and tapered tail part 100b created when the gold wire is torn. In FIG. 8, film 106 coated around electrode pad 104 on semiconductor chip 102 is a surface protection film or a passivation film.

In order to mount this kind of semiconductor chip 102 onto a printed board using the flip-chip scheme, a method combining an ultrasonic bonding method and a thermocompression bonding method is usually utilized. More specifically, as shown in FIG. 9(A), semiconductor chip 102 is placed face down (facing downward) against printed board 108 to place tip of tail part 100b of each stud bump 100 against conductive film 110 on the substrate, and heat at a prescribed temperature is applied from the side of the stage (not illustrated) on which printed board 108 is mounted. In the meantime, an ultrasonic wave is applied from above semiconductor chip 102 using an ultrasonic wave oscillator (not illustrated). Then, as shown in FIG. 9(b), stud bump 100 is compression-bonded onto conductor 110 as it is crushed from the tip side of tail part 100b, and pedestal part 100a is bonded firmly onto conductive film 110.

The positions, shapes and sizes of the bumps are likely to become non-uniform because the aforementioned conventional stud bump is created by tearing the gold wire on each electrode pad 104 while moving semiconductor (chip 102 in the XY direction on the XY stage. Furthermore, because bumps 100 are created one by one in series (in order) on respective electrode pads 104, the amount of labor increases in proportion to the number of bumps per chip or wafer.

In addition, because tail part 100b which is nearly a half or more of stud bump 100 is tapered due to the tearing, it is very difficult to set the probe pin of a probe device there precisely and reliably. So, a probing test is virtually impossible once the bump is created. Furthermore, because tail part 100b of stud bump 100 has been hardened through recrystallization and sharpened through tapering, it cannot be compression-bonded to electrode pad 104 smoothly, and it gets deformed easily during its transportation in a wafer case or a chip tray when it comes into contact with the lid of the container.

In addition, as described above, when an ultrasonic wave compression bonding method is utilized during the flip-chip mounting, chip 102 is subjected twice to the stress due to the ultrasonic wave compression bonding, including the one during the formation of the bump, so that the integrated circuit inside of pad 104 may get damaged.

The present invention was made with regard to the aforementioned problems of the prior art, and its purpose is to present a semiconductor device and a bump formation method by which accuracy in terms of the position, shape, and size of the bump can be improved in order to realize highly reliable flip-chip mounting.

Another purpose of the present invention is to present a semiconductor device and a bump formation method in which batch treatment is used for bump formation in order to reduce the cost per 1 bump.

Another purpose of the present invention is to present a semiconductor device and a bump formation method which enables a probing test after the formation of the bump.

Another purpose of the present invention is to present a semiconductor device and a bump formation method by which the physical strength of the bump can be reinforced in order to improve the mounting efficiency and the reliability during the transportation.

### SUMMARY OF THE INVENTION

In order to achieve the aforementioned objectives, the semiconductor device of the present invention has a configuration in which a bump having a near flat peak plane created by depositing a metallic film onto an electrode is provided on the main surface of a semiconductor device. With said configuration, because the peak plane of the bump is formed into a flat surface, the probing pin can be placed on the bump (peak plane) precisely and reliably, so that the probing test can be carried out after the bump is created.

It is desirable that the semiconductor device of the present invention has a configuration in which the diameter of the bump is reduced by at least one step at a point between the bottom part and the top part of the bump. In such case, it is preferable that the bump has a shape in which multiple substantially columnar bodies with different cross-sectional dimensions are stacked coaxially in multiple steps in such an order that its cross-sectional dimensions get smaller toward the top. With such a configuration, the bump can be provided with a pedestal part and a tail part, so that the flip-chip mounting can be carried out more effectively and accurately. In the present invention, a desirable material for the bump is gold plating.

The first bump formation method of the present invention involves a step in which an electrode pad is created at a prescribed position on the main surface of a semiconductor substrate formed monolithically with an electronic circuit, a step in which a passivation film is formed on the main surface of the aforementioned semiconductor substrate in such a manner that the aforementioned pad gets exposed, a step in which a seed layer for electrolysis is formed on the aforementioned electrode pad and the aforementioned passivation film, a step in which a first resist film is formed on the aforementioned seed layer, a step in which patterning is applied to the aforementioned first resist film in order to create a first opening part with a prescribed shape on the aforementioned electrode pad by removing the aforementioned first resist film locally, a step in which a first plated film made of a conductive metal is formed in the aforementioned first opening part using the aforementioned patterned first resist film as a mask, a step in which a second resist film is formed on the aforementioned first resist film and the aforementioned first plated film, a step in which patterning is applied to the aforementioned second resist film in order to create a second opening part with a prescribed shape above the center of the aforementioned first plated film by removing the aforementioned second resist film locally, a step in which a second plated film made of a conductive metal is formed in the aforementioned second opening part using the aforementioned patterned second resist film as a mask, a step in which the aforementioned first and the aforementioned second resist films are removed, and a step in which the seed layer on the aforementioned passivation film is removed using the aforementioned first and the second plated films as masks.

The second bump formation method of the present invention involves a step in which an electrode pad is created at a prescribed position on the main surface of a semiconductor substrate formed monolithically with an electronic circuit, a step in which a passivation film is formed on the main surface of the aforementioned semiconductor substrate in such a manner that the aforementioned pad gets exposed, a step in which a seed layer for electrolysis is formed on the aforementioned electrode pad and the aforementioned passivation film, a step in which a first resist film is formed on the aforementioned seed layer, a step in which patterning is applied to the aforementioned first resist film in order to create a first opening part with a prescribed shape on the aforementioned electrode pad by removing the aforementioned first resist film locally, a step in which a second resist film formed in advance as a solid film is pasted onto the aforementioned first resist film in such a manner that the opening part on the aforementioned electrode pad is closed at the height of the top surface of the aforementioned first resist film, a step in which patterning is applied to the aforementioned second resist film in order to create a second opening part with a prescribed shape above the center of the aforementioned electrode pad by removing the aforementioned second resist film locally, a step in which a plated film made of a conductive metal is formed in the aforementioned first and the second opening parts to a height in excess at least of the bottom surface of aforementioned second resist film using the aforementioned second resist film as a mask, a step in which the aforementioned first and the second resist films are removed, and a step in which the seed layer on the aforementioned passivation film is removed using the aforementioned plated film as a mask.

With the bump formation methods of the present invention, the bumps can be batch-processed at the wafer stage through the utilization of a resist (photolithography) technology and a plating technology.

### BRIEF DESCRIPTION OF THE DRAWINGS

FIG. 1 is an outlined cross section showing the structure of the crucial part of the semiconductor device in accordance with an embodiment of the present invention.

FIG. 2 is a slated view of the outer shape of the bump in the embodiment.

FIG. 3 are schematics showing an example of the flip-chip mounting pertaining to the semiconductor device of the embodiment.

FIG. 4 are schematics showing an example of another example of the flip-chip mounting which can be applied to the semiconductor device of the embodiment.

FIG. 5 are schematics showing the steps in the first bump formation method in the embodiment.

FIG. 6 are schematics showing the steps in the second bump formation method in the embodiment.

FIG. 7 is a cross section showing a modification example of the bump shape in the embodiment.

FIG. 8 is an outlined cross section showing the configuration of the semiconductor device having the conventional stud bump.

FIG. 9 are schematics showing an example of the flip-chip mounting pertaining to the conventional semiconductor device.

### REFERENCE NUMERALS AND SYMBOLS AS SHOWN IN THE DRAWINGS

In the figures, 10 is a semiconductor chip, 12 an electrode pad, 14 a Bump, 14a a pedestal part, 14b a tail part, 16 a seed layer, 18 a passivation film, 30, 36 are resist film, 32, 38 are opening part, 34, 40 are gold plated film, 42 a film resist, 44 an opening part, and 46 a gold plated film.

### DESCRIPTION OF EMBODIMENTS

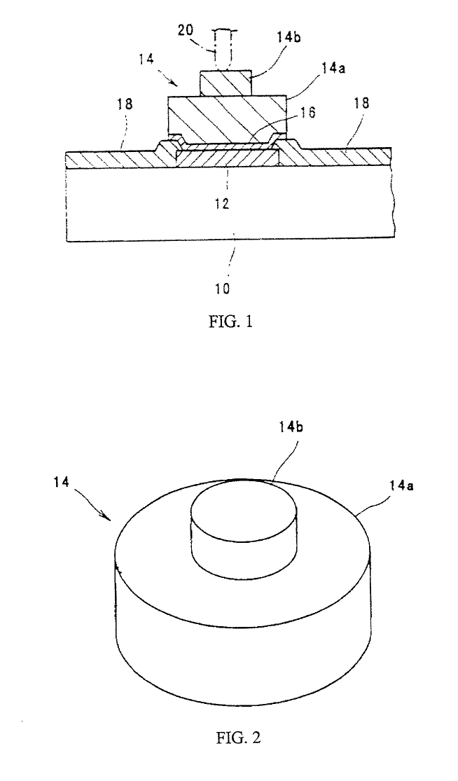

Embodiments of the present invention will be explained in reference to FIGS. 1 through 7.

A cross-sectional structure of a part of the semiconductor device in accordance with an embodiment of the present invention is shown in FIG. 1. The outer shape of the bump in said semiconductor device is shown in FIG. 2.

In the case of the semiconductor device in the present embodiment, as shown in the figures, 2-column-pile type or convex-cross-section type bump 14 is provided on electrode pad 12 created on the main surface of semiconductor device 10. Here, 2-column-pile type (convex-cross-section type) refers to the shape for which a second columnar body with a second diameter smaller than a first diameter of a first columnar body is piled coaxially on top of the latter. 2-column-pile type (convex-cross-section type) bump 14 in the present embodiment comprises pedestal part 14a made of the first columnar body and tail part 14b made of the second columnar body. This kind of bump shape is characteristic in that the peak plane (peak plane of the bump) of tail part 14b and the top surface of pedestal part 14a are both flat, and that tail part 14b stands upright with a fixed diameter perpendicularly from the top surface of pedestal part 14a.

As it will be described later, such a 2-column-pile type bump 14 may be created using a resist (photolithography) technology and a plating technology, and although any conductive metal may be used as the bump material as long as it has a sufficient bonding property and a plating property, gold (Au) is usually desirable. To create bump 14 by gold plating, it is desirable to use an electrolytic plating method in order to obtain a sufficient plating thickness, that is, a bump height. In this case, sheath layer 16 coated on electrode pad 12 during the electrolytic plating treatment remains below bump 14 after the bump is created. Said sheath layer 16 also has a function of protecting pad 12 against the pressure or the stress applied from above the bump during the bonding for flip-chip mounting, and it may be formed using TiW.

As for semiconductor chip 10, an electronic circuit is created monolithically on the main surface of a silicon substrate by the conventional semiconductor process, and electrode pad 12 is provided at a prescribed position on top of it via an interlayer insulating film (not illustrated), and passivation film 18 made of Si₃N₄, for example, is coated around each pad 12. Electrode pad 12 may be made of an aluminum-copper alloy (AlCu), for example; and a barrier metal made of TiW, for example, may be laid between and the base film, that is, the interlayer insulating film (SiO₂).

In the case of the semiconductor device in the present embodiment, because the peak plane of bump 14 is created flat, as shown in FIG. 1, probe pin 20 can be placed against bump 14 reliably and precisely. In terms of the size of bump 14, the diameter and the height of pedestal part 14a may be 122 μm and 23 μm, respectively, and the diameter and the height of tail part 14b may be 43 μm and 15 μm, respectively.

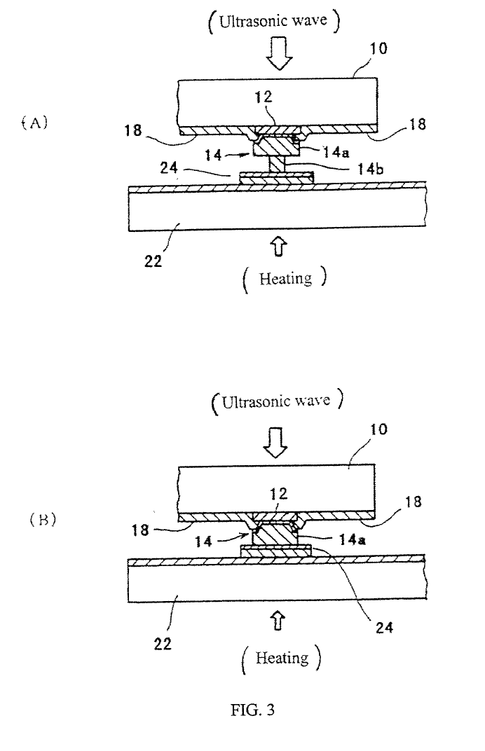

An example of the flip-chip mounting pertaining to the semiconductor device of the present embodiment is shown in FIG. 3. Like the prior art in FIG. 8, the ultrasonic wave bonding method and the thermocompression bonding method are utilized in combination in this example. in other words, as shown in FIG. 3(A), semiconductor chip 10 is placed face down (facing downward) against printed board 22 to place the tip of tail part 14b of each bump 14 against conductive film 24 on the substrate, and heat at a prescribed temperature is applied from the side of the stage (not illustrated) on which printed board 22 is mounted. In the meantime, an ultrasonic wave is applied from above semiconductor chip 10 using an ultrasonic wave oscillator (not illustrated). Then, as shown in FIG. 3(B), the bump is compression-bonded onto conductor film 24 as the bump tail part 14b and then the bump pedestal part is pressed firmly onto conductive film 24. Furthermore, an insulating film may be coated on the surface of a substrate main body made of an epoxy resin, for example, for printed board 22; and conductive film 24 on the substrate may be a copper plated film or a copper foil coated with a thin film made of a nickel alloy (for example, Ni—Au) on its surface.

In the present embodiment, because bump 14 is provided as a gold plated film on electrode pad 12 on semiconductor chip 10, no stress is applied to pad 12 or any nearby circuit part during the formation of the bump. Therefore, electrode pad 12 is subjected to stress only one time even when the aforementioned ultrasonic bonding method is used during the flip-chip mounting, so that damage can be avoided.

In addition, because bump 14 of semiconductor chip 10 is created using the resist (photolithography) technology and the plating technology, the position, shape, and size of the bump are highly precise, so that it can be positioned accurately onto respective corresponding conductive film 24 on printed board's 22 side. Moreover, because tail part 14b of bump 14 is not recrystallized, and the entire bump is created using a uniform material (gold plating), a good pressure-bonding property or a bonding characteristic with respect to conductive film 24 can be obtained. In addition, because tail part 14b of bump 14 is made of the columnar body and has a high level of physical strength, bump 14 is unlikely to get deformed even if it comes into contact with the lid of the wafer case or the chip tray during the storage or the transportation prior to the flip-chip mounting.

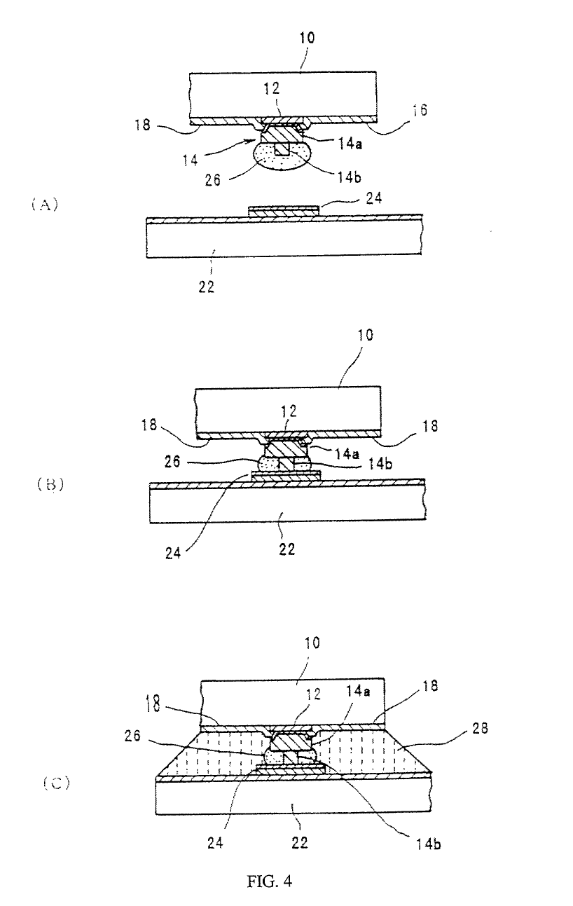

Another example of flip-chip mounting which can be applied to the semiconductor device of the present embodiment is shown in FIG. 4. In said flip-chip mounting method, conductive filler or paste 26 is laid between bump 14 on semiconductor chip's 10 side and conductive film 24 on printed board's 22 side in order to establish an electrical connection between them via said conductive filler 26, and thermal-shrinkage-curing underfiller 28 is loaded between semiconductor chip 10 and printed board 22 in order to bond them into one body by means of the thermal shrinkage force of said underfiller 28.

As shown in FIG. 4(A), semiconductor chip 10 is placed face down, and conductive filler 26 is transferred (adhered) around tail part 14b of bump 14 in advance. A right-angle step is created between tail part 14b and pedestal part 14a. Conductive filler 26 is well transferred and kept in a stable fashion at said step part.

As shown in FIG. 4(B), semiconductor chip 10 is placed face down on printed board 22, so that conductive filler 26 adhered on each bump 14 is also adhered onto each conductive film 24 on the substrate. Although tail part 14b of bump 14 may be brought into contact with conductive film 24, it is not essential to do so.

As shown in FIG. 4(C), thermal-shrinkage-curing underfiller 28 adheres to the respective parts while filling the space between semiconductor chip 10 and printed board 22 and shrinks and cures by heating to form a mold.

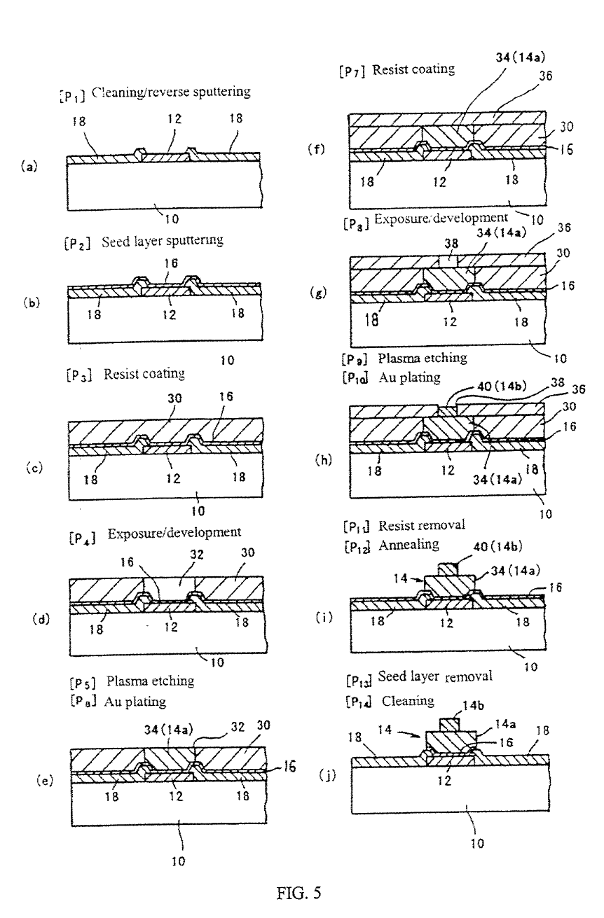

Next, the first method for creating bump 14 in the semiconductor device of the present embodiment will be explained in the order of the steps therein according to FIG. 5. Furthermore, the steps in the figure may all be executed at the semiconductor wafer stage.

First, once an integrated circuit is created on the main surface of the silicon substrate of semiconductor chip 10 using the conventional semiconductor process, and electrode pad 12 and passivation film 18 are formed on top of it via an interlayer insulating film (not illustrated), the main surface of the wafer (chip 10) is cleaned first in Step P1, and reverse sputtering as a pretreatment prior to the plating step is applied in order to obtain a rough surface (FIG. 5(a)).

Next, a titanium tungsten (TiW) film, for example, as seed layer 16 for electrolytic plating is coated over the entire main surface of semiconductor chip 10 by sputtering in Step P2 (FIG. 5(b)).

Next, in Step P3, a resist solution is applied on seed layer 16 using a spin coating method, for example, and dried in order to form resist film 30 (FIG. 5(c)). Here, it is desirable to bring the film thickness of resist film 30 close to the height (a set value) of pedestal part 14a of bump 14.

Next, in Step P4, patterning (exposure/development) is applied to resist film 30 in order to create opening part 32 with a prescribed opening diameter on electrode pad 12 (FIG. 5(d)). Diameter of said opening part 32 defines the diameter of pedestal part 14a of bump 14.

Next, in Step P5, organic contaminants in opening part 32 are removed through plasma etching in order to clean the exposed surface of seed layer 16.

Next, in Step P6, gold plated film 34 is formed on seed layer 16 in opening part 32 by means of the electrolytic plating method using resist film 30 as a mask, preferably in such a manner that the inside of opening part 32 is completely filled (FIG. 5(e)). Said gold plated film 34 constitutes pedestal part 14a of bump 14. Furthermore, because seed layer 16 is the cathode during the electrolytic plating, it may be partially exposed from one end of said semiconductor wafer and connected to the cathode electrode on the plating power source.

Next, in Step P7, a resist solution is applied onto resist film 30 and gold plated film 34 by means of the spin coating method, for example, and dried in order to form resist film 36 as the top layer (FIG. 5(f)). Here, it is desirable to make the film thickness of said top layer resist film 36 close to the height (a set value) of tail part 14b of bump 14.

Next, in Step P8, patterning (exposure/development) is applied to top layer resist film 36 in order to create opening part 38 with a prescribed opening diameter above the center of gold plated film 34 (FIG. 5(g)). Diameter of said opening part 38 defines the diameter of tail part 14b of bump 14.

Next, in Step P9, organic contaminants in opening part 38 are removed through plasma etching in order to clean the exposed surface of gold plated film 34.

Next, in Step P10, top layer gold plated film 40 is formed on gold plated film 34 in opening part 38 by means of the electrolytic plating method using top layer resist film 36 as a mask, preferably in such a manner that inside of opening part 38 is completely filled (FIG. 5(h)). Said top layer gold plated film 40 constitutes tail part 14b of bump 14.

Next, in Step P11, resist films 30 and 36 of both layers are removed by ashing.

Next, in Step P12, bump 14 (14a, 14b) made of gold plated film 34, 38 is annealed at a prescribed temperature in order to increase its density (FIG. 5(i)).

Next, in Step P13, seed layer 16 is removed through etching using bump 14 as a mask (FIG. 5(j)). As a result, seed layer 16 remains only between bump 14 and electrode pad 12. Finally, in Step P14, cleaning is applied.

After bump 14 is created on the main surface of semiconductor chip 10 in the aforementioned manner, the product quality of the chip is inspected using a prober. As shown in FIG. 1, in the present embodiment, because probing pin 20 can be placed onto 2-column-pile type (convex-cross-section type) bump 14 reliably and precisely, a highly reliable probing test can be realized. Moreover, said semiconductor wafer may be divided into respective chips 10 after the probing test is performed.

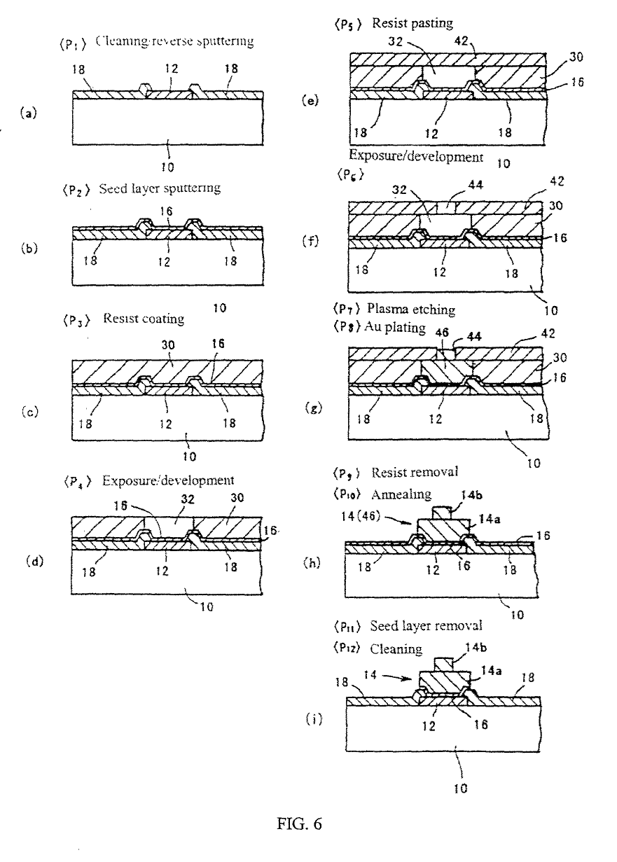

A second method for creating bump 14 in the semiconductor device of the present embodiment is shown in FIG. 6. In this bump formation method, the process from Step P1 through Step P4 may be identical to Steps P1 through P4 in the aforementioned first method.

However, a solid film resist is pasted as top resist layer 42 onto resist film 30 in Step P5 (FIG. 6(e)). It is desirable to make the film thickness of said top layer resist film 42 close to the height (a set value) of tail part 14b of bump 14. Opening part 32 on electrode pad 12 created on bottom resist film 30 is temporarily covered by said top layer resist film 42.

Next, in Step P6, patterning (exposure/development) is applied to top resist film 42 in order to create opening part 44 with a prescribed opening diameter above the center of electrode pad 12 (FIG. 6(f)). The diameter of said opening part 44 defines the diameter of tail part 14b of bump 14. Opening part 32 on bottom resist film's 30 side gets connected (aligned) to opening part 44 through opening part 44 on said top resist film 42 and creates an opening part with a convex cross-sectional shape.

Next, in Step P7, organic contaminants in opening parts 38 and 44 are removed through plasma etching in order to clean the exposed surface of seed layer 16.

Next, in Step P8, convex-cross-section type, that is, 2-column-pile type, gold plated film 46 is formed on electrode pad 12 in opening parts 32 and 44 by 1 round of the plating process, preferably in such a manner that opening parts 32 and 44 are filled completely, by means of the electrolytic plating method using bottom layer resist film 30 and top layer resist film 42 as masks (FIG. 6(g)).

Subsequent steps P9 through P12 are substantially identical to Steps P11 through P14 in the aforementioned first method.

As described above, in the present embodiment, bump 14 of semiconductor chip 10 can be batch-processed at the semiconductor wafer stage using the resist (photolithography) technology and the plating technology. Thus, work time does not need to be increased even when the number of bumps per chip or wafer is increased, so that the bump cost can be reduced significantly.

Although bump 14 of semiconductor chip 10 was configured by gold plating in the aforementioned embodiment, other metals can also be used for the plating. In addition, nonelectrolytic plating may also be utilized as long as a sufficient plating film thickness can be obtained. The shape of the bump in the present invention is not limited to the 2-column-pile type (convex-cross-section type), and a variety of modifications are also possible.

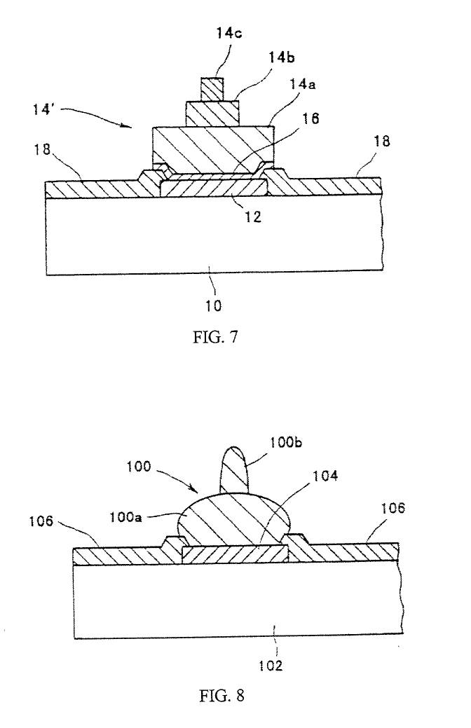

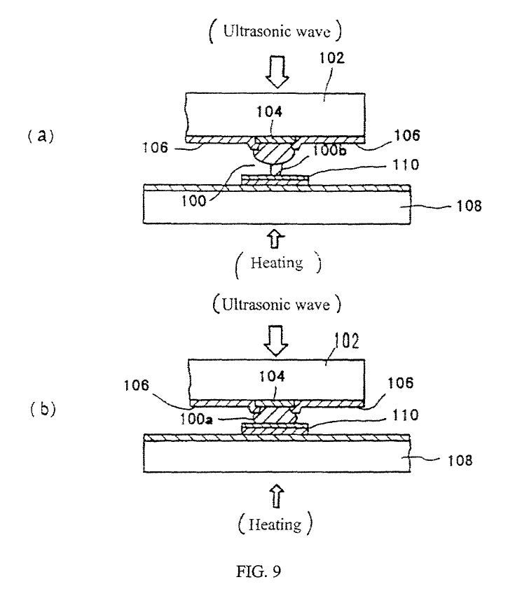

For example, as shown in FIG. 7, a shape obtained by piling up 3 columnar bodies with different diameters coaxially, that is, 3-column-pile type bump shape 14′, is also feasible. In this case, third columnar body 14c with a smaller diameter than that of second columnar body 14b is piled up coaxially on top of this columnar body 14b in multiple steps, and said topmost columnar body 14c constitutes the tip part of the tail part. When such 3-column-pile type bump shape 14′ is adopted, the bump height can be increased easily by piling up the 3 layers of plated films, and the overall shape of the bump, particularly, the shape at the tail part, can be flexibly designed. In addition, the cross section of the bump in the present invention can also be made into an oval or a polygonal shape.

Although gold was exemplified as the material for the bump in the embodiments described above, it should be clear for those in the field that nickel (Ni), copper (Cu), palladium (Pd), and so forth can also be used as the material.

As it has been described above, with the semiconductor device of the present invention or the bump formation method, accuracy in terms of the position, shape, and size of the bump can be improved in order to realize highly reliable flip-chip mounting. In addition, they are advantageous in that the bump cost can be reduced by creating the bump through patch processing, and that deformation of the bump can be reduced as much as possible.

1. A semiconductor device, comprising:
a contact pad;
a conductive bump on said contact pad, said bump comprising a coaxially-aligned stack of bodies having different cross-sectional dimensions, said bodies at the top of said stack having smaller cross-sectional dimensions.

2. The semiconductor device described in claim 1 in which the uppermost body in said stack has a flat peak plane.

3. The semiconductor device described in claim 1 in which the coaxially-aligned bodies are circular.

4. The semiconductor device described in claim 1 in which the bodies are made of gold.

5. The semiconductor device described in claim 2 in which the bodies are made of gold.

6. The semiconductor device described in claim 3 in which the bodies are made of gold.

7. A method for forming a conductive bump on a semiconductor device including:
providing an electrode pad at a prescribed position on the main surface of a semiconductor substrate formed monolithically with an electronic circuit;
forming a passivation film on the main surface of the semiconductor substrate such that the pad is exposed;
forming a seed layer for electrolysis on the electrode pad and the passivation film;
forming a first resist film on the seed layer;
patterning the first resist film in order to create a first opening part with a prescribed shape on the electrode pad by locally removing the first resist film;
forming a first plated film made of a conductive metal in the first opening part using the patterned first resist film as a mask;
forming a second resist film on the first resist film and the first plated film;
patterning the second resist film in order to create a second opening part with a prescribed shape above the center of the first plated film by locally removing the second resist film;
forming a second plated film made of a conductive metal in the second opening part using the patterned second resist film as a mask;
removing the first and the second resist films; and
removing the seed layer on the passivation film using the first and the second plated films as masks.

8. A method for forming a conductive bump on a semiconductor device, comprising the steps of:
providing an electrode pad at a prescribed position on the main surface of a semiconductor substrate formed monolithically with an electronic circuit;
forming a passivation film on the main surface of the semiconductor substrate such that the pad is exposed;
forming a seed layer for electrolysis on the electrode pad and the passivation film;
forming a first resist film on the seed layer;
patterning the first resist film in order to create a first opening part with a prescribed shape on the electrode pad by locally removing the first resist film;
forming a second resist film on the first resist film to cover the first opening part on the electrode pad;
patterning the second resist film in order to create a second opening part with a prescribed shape above the electrode pad by locally removing the second resist film;
forming a plated film made of a conductive metal in the first and the second opening parts to a height in excess at least of the bottom surface of the second resist film using the second resist film as a mask;
removing the first and the second resist films;, and
removing the seed layer on the passivation film using the plated film as a mask.
